(19) United States
(12) Patent Application Publication
(10) Pub. No.: US 2006/0179642 A1
(43) Pub. Date: Aug. 17, 2006

(54) Method for manufacturing a film bulk acoustic resonator

(75) Inventor: Yoshihisa Kawamura, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/337,484

(22) Filed: Jan. 24, 2006

(30) Foreign Application Priority Data
Feb. 3, 2005 (JP) P2005-028101

(51) Int. Cl. H01L 41/08; H04R 31/00

(52) U.S. Cl. 29/594; 29/609.1; 310/334

(57) ABSTRACT

A method for manufacturing a film bulk acoustic resonator includes forming a closed room in a supporting substrate; forming a bottom electrode above the closed room, the bottom electrode provided on a surface of the supporting substrate; forming a piezoelectric film on a surface of the bottom electrode; forming a top electrode facing the bottom electrode to sandwich the piezoelectric film; forming an opening connected to the closed room from the surface of the supporting substrate; and forming a cavity by removing a portion of the supporting substrate under the bottom electrode through the opening and the closed room.

### CROSS REFERENCE TO RELATED APPLICATIONS AND INCORPORATION BY REFERENCE

This application is based upon and claims the benefit of priority from prior Japanese Patent Application P2005-28101 filed on Feb. 3, 2005; the entire contents of which are incorporated by reference herein.

### BACKGROUND OF THE INVENTION

1. Field of the Invention

The present invention relates to a method for manufacturing a film bulk acoustic resonator having a cavity.

2. Description of the Related Art

Recently, wireless communication systems, such as mobile telecommunication devices, and high-speed data transfer wireless local area networks (LAN) use high frequency bands which exceed the GHz range. A film bulk acoustic resonator (FBAR) is used as a high frequency element in such types of high frequency electronic equipment for wireless communication systems.

In the past, bulk (ceramic) dielectric resonators, surface acoustic wave elements (SAW) have been used as resonators for high frequency bands. Compared to these resonators, the FBAR is better suited for miniaturization, and has attributes allowing the FBAR to respond better to even higher frequencies. Thus, there is continued development of high frequency filters and resonance circuits using the FBAR.

In a basic structure of a FBAR, a piezoelectric film, such as aluminum nitride (AlN) and zinc oxide (ZnO), is sandwiched between a bottom electrode and an opposed top electrode. A resonator of the FBAR is disposed above a cavity provided below the first electrode, in order to attain high performance. In general, the piezoelectric film has a larger area than the first and second electrodes.

The FBAR is manufactured in the same manner as an integrated circuit manufactured on a semiconductor substrate. For improving performance of the FBAR, a resonator of the FBAR is disposed so as to be suspended above a cavity.

A proposed manufacturing method for a suspended FBAR selectively removes a portion of a substrate below a resonator from a backside of the substrate after fabricating the FBAR. More specifically, a portion of a silicon (Si) substrate below the resonator of the FBAR is selectively removed by anisotropic wet etching or deep reactive ion etching (DRIE), so as to form a cavity.

When forming a cavity by wet etching, since the substrate is immersed in the etching solution for a long time, the etching solution may sink into the resonator of the FBAR to deteriorate resonant characteristics. Additionally, a processing conversion difference of a finished dimension corresponding to a mask dimension of the cavity may increase, so that there is a disadvantage in that the FBAR cannot be densely arranged on the substrate. Therefore, miniaturization of the FBAR is difficult.

In a case of DRIE, it is possible to increase an etching rate by selecting etching conditions. Additionally, by DRIE, substantially vertical sidewalls of the cavity can be achieved. Therefore, by using highly anisotropic DRIE, it is possible to solve problems such as deterioration of the resonant characteristics and increase of the processing conversion difference. However, since the cavity is formed after polishing the substrate to a thickness in a range of about 200 μm to about 300 μm, mechanical strength of the substrate may be decreased. Thus, handling of the substrate may become difficult.

There is another manufacturing method for a suspended FBAR, in which a groove formed in the substrate is filled with a sacrificial material, and the FBAR is formed on the sacrificial material (refer to United State Patent Application Specification No. 6060818). After forming the FBAR, the sacrificial material is removed to form a cavity. For example, in order to fill the groove in the substrate, deposition of a sacrificial film such as phosphosilicate glass (PSG), and removal and planarization of unwanted portion of the sacrificial film by chemical mechanical polishing (CMP) are carried out. In such a case, CMP may cause dishing, due to a hardness difference between the sacrificial film and the substrate. Orientation of the piezoelectric film of the FBAR, which is important for resonant characteristics of the FBAR, may deteriorate due to deterioration of flatness of the surface of the sacrificial film caused by dishing.

### SUMMARY OF THE INVENTION

An aspect of the present invention inheres in a method for manufacturing a film bulk acoustic resonator including forming a closed room in a supporting substrate; forming a bottom electrode above the closed room, the bottom electrode provided on a surface of the supporting substrate; forming a piezoelectric film on a surface of the bottom electrode; forming a piezoelectric film on a surface of the bottom electrode; forming a top electrode facing the bottom electrode so as to sandwich the piezoelectric film between the top electrode and the bottom electrode; forming an opening connected to the closed room from the surface of the supporting substrate; and forming a cavity by removing a portion of the supporting substrate under the bottom electrode through the opening and the closed room.

### BRIEF DESCRIPTION OF DRAWINGS

FIG. 1 is a plan view showing an example of a FBAR according to an embodiment of the present invention.

FIG. 2 is cross sectional view taken on line II-II of the FBAR shown in FIG. 1.

FIG. 3 is cross sectional view taken on line III-III of the FBAR shown in FIG. 1.

FIG. 4 is a cross sectional view showing an example of a method for manufacturing a FBAR according to the embodiment of the present invention.

FIG. 5 is a plan view showing an example of a method for manufacturing a FBAR according to the embodiment of the present invention.

FIG. 6 is cross sectional view taken on line VI-VI of the FBAR shown in FIG. 5.

FIG. 7 is a cross sectional view showing an example of a method for manufacturing a FBAR according to the embodiment of the present invention.

FIG. 8 is a cross sectional view showing an example of a method for manufacturing a FBAR according to the embodiment of the present invention.

FIG. 9 is a plan view showing an example of a method for manufacturing a FBAR according to the embodiment of the present invention.

FIG. 10 is cross sectional view taken on line X-X of the FBAR shown in FIG. 9.

FIG. 11 is a view showing an example of a method for forming a cavity according to the embodiment of the present invention.

FIG. 12 is a view showing an example of a method for forming a cavity according to other embodiments of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

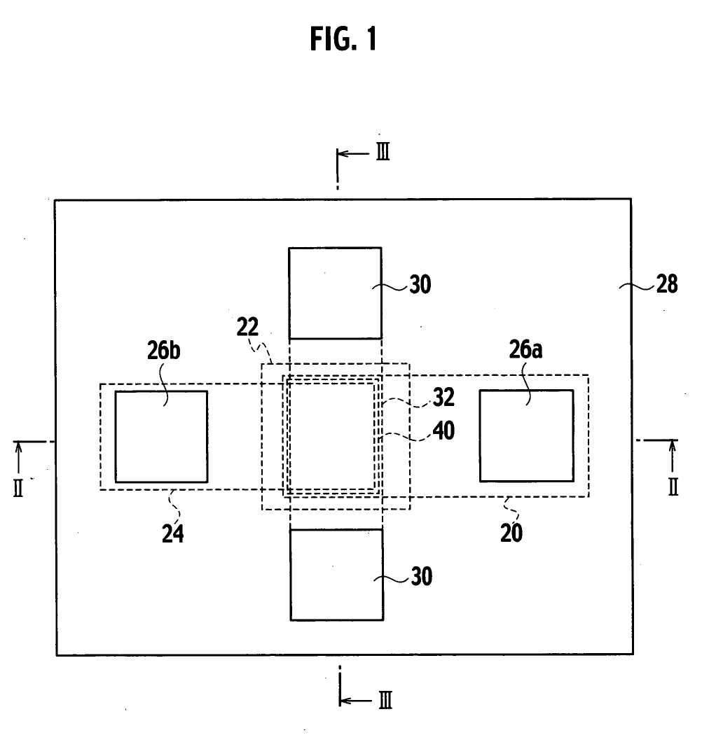

A FBAR according to an embodiment of the present invention, as shown in FIGS. 1 to 3, includes a bottom electrode 20, a piezoelectric film 22, and a top electrode 24. The bottom and top electrodes 20, 24 are disposed so as to face each other and to sandwich the piezoelectric film 22. A cavity 32 is provided in a supporting substrate 17 including a first mother substrate 10 and a second mother substrate 16 bonded on the first mother substrate 10 by an adhesive layer 12. The cavity 32 extends, in a depth direction, from an insulating film 18 on a surface of the second mother substrate 16 to an interior portion of the first mother substrate 10.

The bottom electrode 20 is disposed so as to extend across the cavity 32 from an end region of the cavity 32 to a surface of the insulating film 18. The top electrode 24 is disposed so as to extend from a region above the cavity 32 to the surface of the insulating film 18 adjacent the end region of the cavity 32. Openings 30 connected to the cavity 32 are provided in a protection film 28 provided on a surface of the FBAR in a direction perpendicular to the direction in which the bottom and top electrodes 20, 24 extend. Additionally, bonding pads 26a and 26b, the surfaces of which are exposed in windows provided on the protection film 28, are disposed at opposite ends of the bottom and top electrodes 20, 24 so as to sandwich the cavity 32. In addition, a resonator 40 is defined by a region in which the bottom and top electrodes 20, 24 face each other to sandwich the piezoelectric film 22, above the cavity 32.

A high frequency signal is transmitted in the piezoelectric film 22 in the resonator 40 by the resonance of bulk acoustic waves excited by a high frequency signal applied to the bottom or top electrode 20, 24. For example, a GHz range high frequency signal that is applied from the bottom electrode 20 is transmitted to the top electrode 24 through the piezoelectric film 22 in the resonator 40.

In order to achieve a favorable resonant characteristic of the resonator 40, an AlN film, a ZnO film and the like, which have excellent film quality, including crystal orientation and uniformity of film thickness, may be used as the piezoelectric film 22. For the bottom electrode 20, a laminated metal film such as aluminum (Al) and tantalum aluminum (TaAl), a refractory metal such as molybdenum (Mo) and tungsten (W), and the like, may be used. For the top electrode 24, a metal such as Al, a refractory metal such as Mo and W, and the like, may be used. For the bonding pads 26a, 26b, a metal such as gold (Au) and Al and the like, may be used. As the protection film 28, silicon nitride (Si₃N₄), AlN, and the like may be used. As the first mother substrate 10 and the second mother substrate 16, a semiconductor substrate such as silicon (Si), having the (110) orientation, may be used. As the adhesive layer 12 and the insulating film 18, silicon oxide (SiO₂) and the like may be used.

In the FBAR according to the embodiment of the present invention, a depth of the cavity 32 is, for example, in a range of about 50 μm to about 200 μm, desirably in a range of about 50 μm to about 100 μm, from the surface of the insulating film 18. Sidewalls of the cavity 32 are substantially vertical in relation to the surface of the first mother substrate 10. As just described, since the cavity is shallow at less than about 200 μm and has the substantially vertical sidewalls, it is possible to decrease the area occupied by the FBAR. Thus, miniaturization of the FBAR is possible. Additionally, thicknesses of the first mother substrate 10 and the second mother substrate 16 are about 600 μm and about 50 μm, respectively. Therefore, it is possible to prevent a decrease of mechanical strength of the first mother substrate 10 and the second mother substrate 16, which support the resonator 40.

A description will be given of a manufacturing method of a FBAR according to the embodiment of the present invention with reference to cross-sectional views and plan views shown in FIGS. 4 to 10.

As shown in FIG. 4, an adhesive layer 12 is formed on a surface of a first mother substrate 10, such as Si, by thermal oxidation. The first mother substrate 10 has a {110} orientation surface and a thickness of about 625 μm. The adhesive layer 12 is a SiO₂ film and the like, having a thickness of about one μm. Note that the thickness of the first mother substrate 10 is not particularly limited if mechanical strength of the first mother substrate 10 can be sufficiently obtained. For example, the first mother substrate 10 may be thicker than about 300 μm. On a rear surface of the first mother substrate 10, an alignment mark, which is omitted in the drawing, is used for positioning of a pattern in subsequent process.

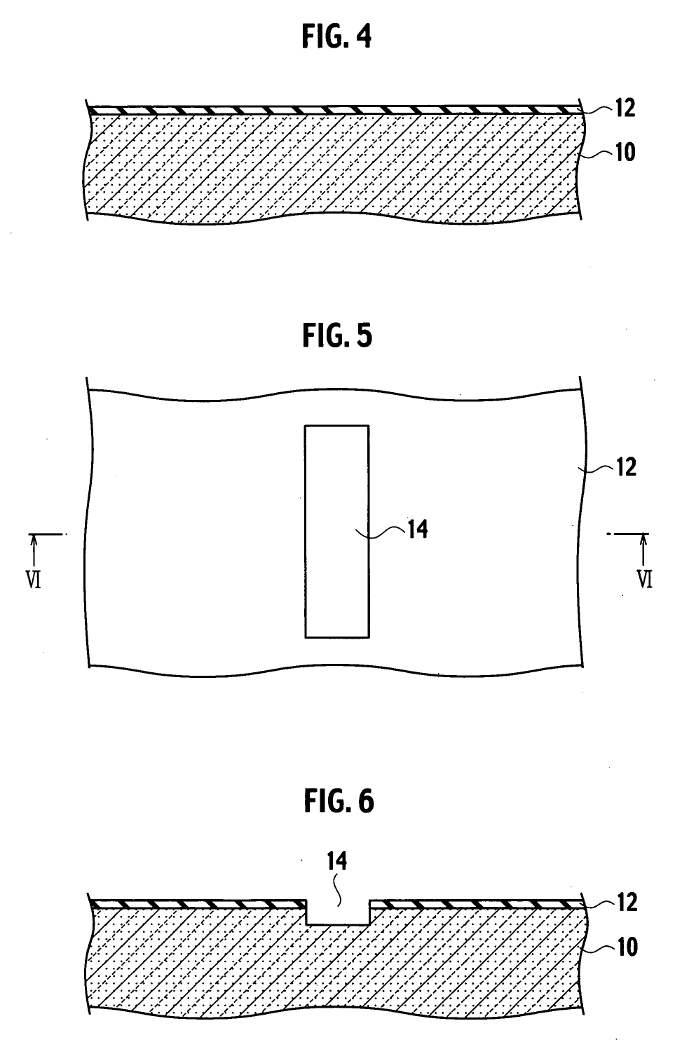

As shown in FIGS. 5 and 6, the adhesive layer 12 and the first mother substrate 10 are selectively removed, by photolithography, RIE and the like, to form a rectangular trench 14 in a part of the adhesive layer 12 and the first mother substrate 10. The trench 14 has a depth of about 50 μm, for example. The depth of the trench is not limited. For example, the depth of the trench 14 may be in a range of about 10 μm to about 100 μm.

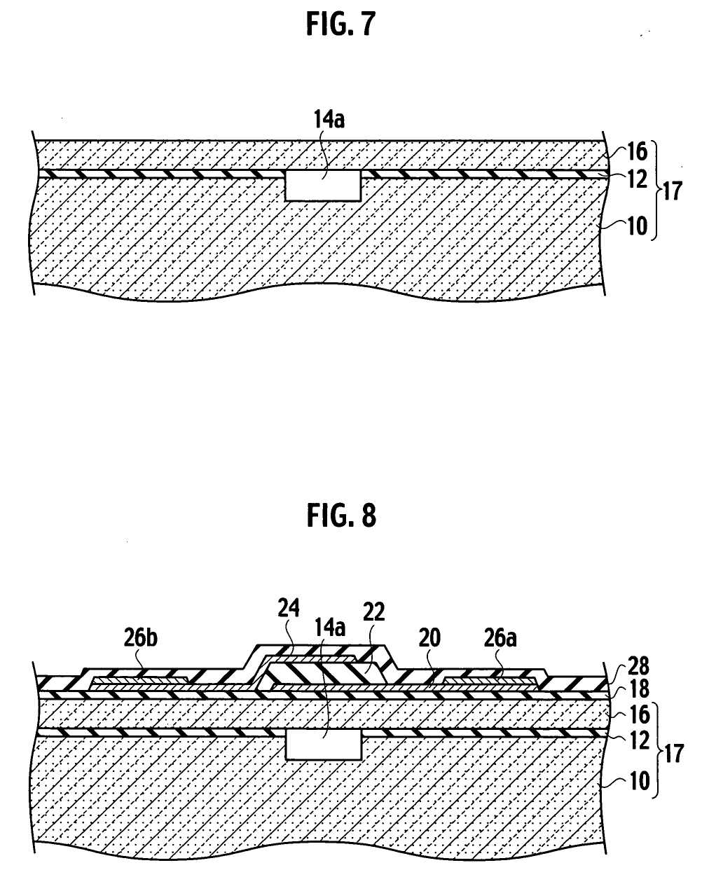

As shown in FIG. 7, a second mother substrate 16 is bonded to the first mother substrate 10 with the adhesive layer 12 so as to internally confine the trench 14 and to form a supporting substrate 17 having a closed room 14a by the internally confined trench 14. The second mother substrate 16 has a {110} orientation surface and a thickness of about 50 μm. The thickness of the second mother substrate 16 is not limited. For example, the thickness of the second mother substrate 16 may be less than about 100 μm. Additionally, after adhering a Si substrate having a thickness of about 625 μm bonded to the first mother substrate 10, the Si substrate may be thinned to a predetermined thickness by CMP, etching, and the like, to provide the second mother substrate 16.

As shown in FIG. 8, an insulating film 18, such as SiO₂, is deposited on the surface of the second mother substrate 16 by chemical vapor deposition (CVD) and the like. A bottom electrode 20, a piezoelectric film 22, a top electrode 24, and bonding pads 26a, 26b are formed on the insulating film 18 by sputtering, photolithography, etching and the like. Subsequently, a protection film 28, such as Si₃N₄, is deposited, by CVD and the like, on the surface of the supporting substrate 17 on which the bottom electrode 20, the piezoelectric film 22, the top electrode 24, and the bonding pads 26a, 26b have been formed.

Here, the bottom electrode 20 is formed above the closed room 14a on the surface of the supporting substrate 17, so as to extend from the vicinity of an end portion of a region corresponding to the closed room 14a, to the other end portion thereof. The piezoelectric film 22 is formed on the surface of the bottom electrode 20, so as to cover an end portion of the bottom electrode 20 in the vicinity of the end portion of the region above the closed room 14a. The top electrode 24 is formed so as to face the bottom electrode 20 and to sandwich the piezoelectric film 22, and to extend to an opposed region of the other end portion to which the bottom electrode 20 extends. The bonding pads 26a, 26b are respectively provided in opposite end portions of the bottom and top electrodes 20, 24.

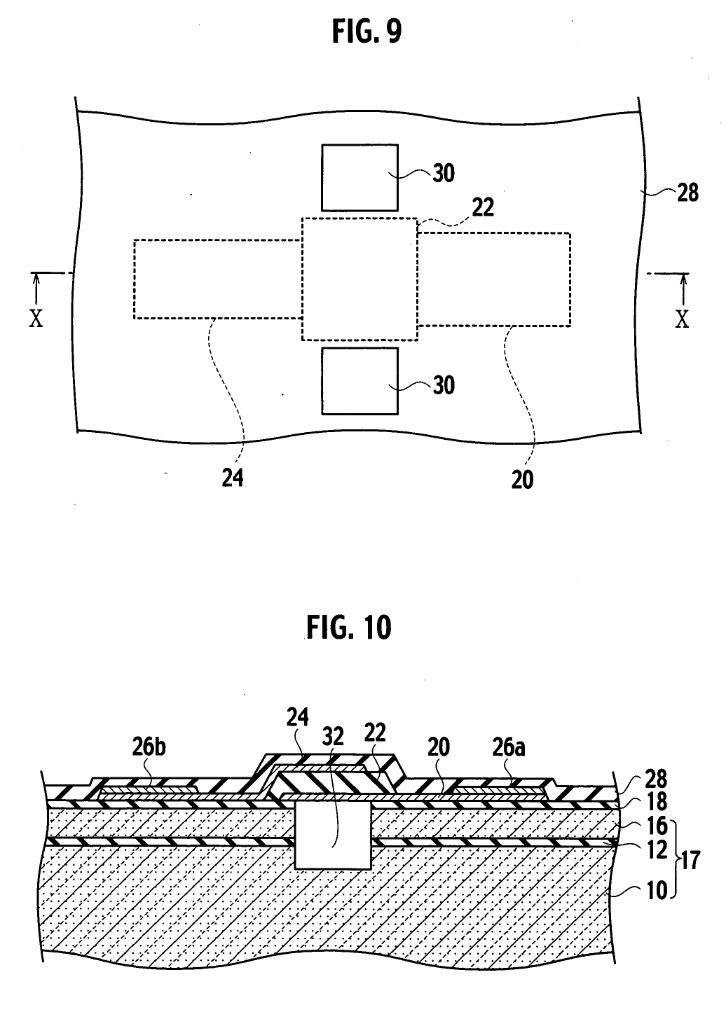

As shown in FIGS. 9 and 10, the insulating film 18 and the second mother substrate 16 in a region spaced from the piezoelectric film 22 on the surface of the protection film 28 above the closed room 14a, are selectively removed, by photolithography, etching and the like, the protection film 28, to form openings 30 connected to the closed room 14a. The second mother substrate 16 under the piezoelectric film 22 is selectively removed, by anisotropic wet etching using a tetramethylammonium hydroxide (TMAH) solution and the like, through the openings 30 and the closed room 14a. Thereafter, the insulating film 18 under the bottom electrode 20 is removed, by wet etching, chemical dry etching (CDE) or the like, until the under side of the bottom electrode 20 is exposed, to form a cavity 32.

Further, the protection film 28 is selectively removed, by photolithography, etching and the like, to expose the surfaces of the bonding pads 26a, 26b. Thus, the FBAR shown in FIGS. 1 to 3 is manufactured.

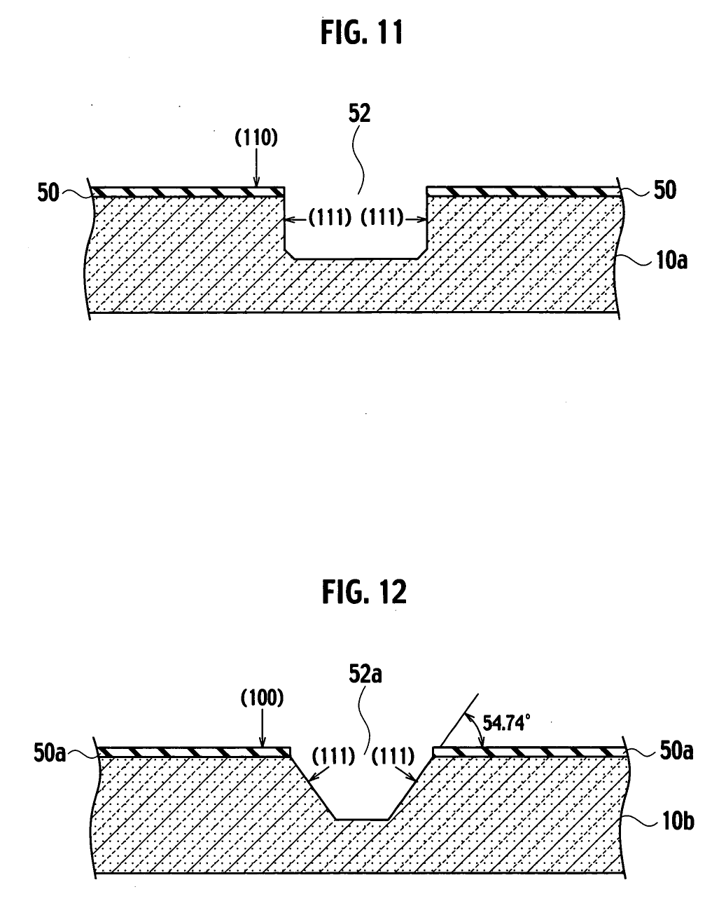

In the embodiment of the present invention, as the first and second mother substrate 10, 16, Si substrates having a {110} orientation are used. For example, wet etching of a Si crystal using a TMAH solution is anisotropic. The {110} plane is selectively etched, while the etching rate for the {111} plane is much less. As shown in FIG. 11, by wet etching using a TMAH solution, a Si substrate 10a having a (110) orientation is selectively removed by using a mask 50 to form a trench 52. A surface of the substrate 10a is a (110) plane. Therefore, a (111) plane, which has low solubility to a TMAH solution, is exposed on sidewalls of the trench 52 perpendicular to the surface of the substrate 10a. As a result, etching mainly progresses in a depth direction of the substrate 10a.

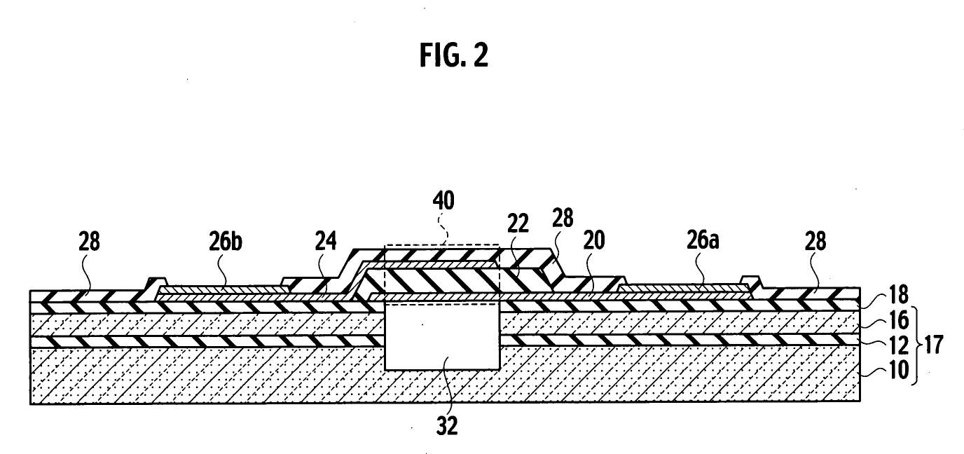

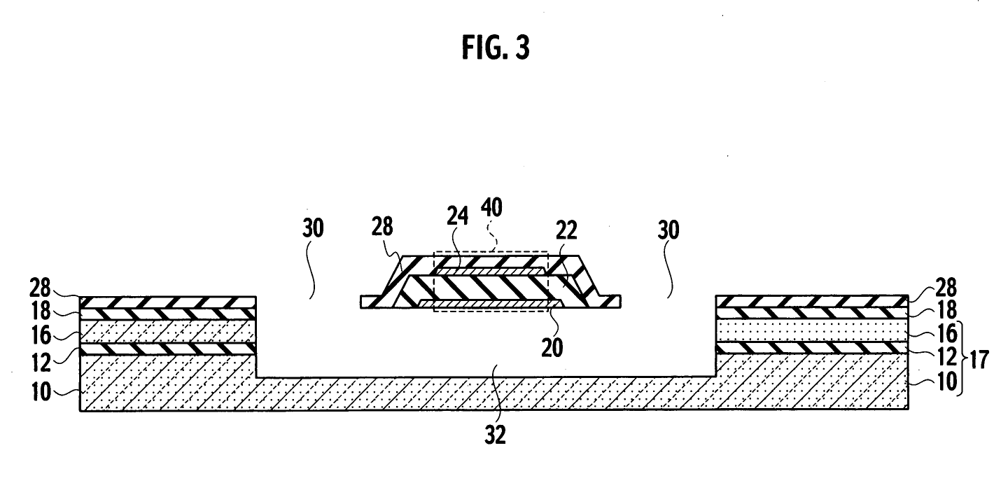

In the embodiment of the present invention, the cavity shown in FIGS. 2 and 3 is formed by selectively removing the second mother substrate 16 on the closed room 14a by anisotropic wet etching. Therefore, since the cavity 32 is limited by the sidewalls having a (111) plane perpendicular to the surface of the second mother substrate 16, a processing conversion difference may be decreased. Additionally, since the thickness of the second mother substrate 16 is about 50 μm, it is possible to decrease the processing time of the cavity 32.

Moreover, in the embodiment of the present invention, as the first mother substrate 10, a Si substrate having a thickness of about 625 μm is used. Therefore, since the first mother substrate 10 has a sufficient mechanical strength, handling of the processing substrate during manufacturing processes may become easier.

Further, the piezoelectric film 22 is deposited on the bottom electrode 20 formed on the insulating film 18 on the surface of the second mother substrate 16. Since the surface of the second mother substrate 16 is flat, it is possible to prevent a deterioration of orientation of the deposited piezoelectric film 22.

Thus, according to the manufacturing method of a FBAR according to the embodiment of the present invention, it is possible to miniaturize a FBAR, to prevent deterioration of the mechanical strength, and to prevent deterioration of resonant characteristics of a FBAR.

Note that, as the adhesive layer 12, a SiO₂ film formed by thermal oxidation is used. However the adhesive layer 12 is not so limited. For example, as the adhesive layer 12, a SiO₂ film deposited by CVD, a Si₃N₄ film, a spin on glass (SOG) film, a spin on dielectric (SOD) film, a polyimide film, a resist film, a carbon film, and the like, may be used.

Additionally, as shown in FIG. 1, the cavity 32 has two rectangular openings 30 provided to pass through both end portions of the cavity 32 in a direction perpendicular to the extending direction of the bottom and top electrode 20, 24. However, one opening or three or more openings may be provided. Further, the openings 30 are not limited to the rectangular shape. For example, a shape of the openings may be a circle, an ellipse, a slit, or the like.

### OTHER EMBODIMENTS

In the embodiment of the present invention, as the first and second mother substrate 10, 16, Si substrates having a {110} orientation are used. However, the substrates are not limited to a {110} orientation. For example, wet etching of a Si crystal using a TMAH solution is also anisotropic such that the etching rate for the {100} plane, similar to the {110} plane, is larger than the {111} plane. As shown in FIG. 12, by wet etching using a TMAH solution, a Si substrate 10b having a (100) orientation is selectively removed by using a mask 50a to form a trench 52a. A surface of the substrate 10b is a (100) plane. Therefore, a (111) plane, which has low solubility to a TMAH solution, is exposed on tilted sidewalls of the trench 52a. The tilted sidewalls of the trench 52a are formed with an angle of theoretically 54.74° with respect to the surface of the substrate 10b. As a result, etching mainly progresses in a depth direction of the substrate 10b. Thus, even using the Si substrates having a (100) orientation as the first and second mother substrates 10, 16, a processing conversion difference may be decreased.

Note that, as the first and second mother substrates 10, 16, the Si substrates having the same orientation are used. However, orientation of the first and second mother substrates may be different. For example, as the first and second mother substrates, Si substrates having (100) and (110) orientations may be used, respectively.

Further, in the embodiment of the present invention, an example has been given for bonding the first and second mother substrates 10, 16 with the adhesive layer 12 after forming the trench 14 in the first mother substrate 10. However, the trench 14 may be formed in the second mother substrate 16. Similarly, the adhesive layer 12 may be formed on the surface of the second mother substrate 16 instead of the first mother substrate 10. In addition, the trench 14 and the adhesive layer 12 may be formed in the first and second mother substrates 10, 16, separately. Further, as the supporting substrate 17, a Si on nothing (SON) substrate, in which an closed room is formed in a Si substrate using an empty space in Si (ESS) technology, may be used.

The present invention has been described as mentioned above. However the descriptions and drawings that constitute a portion of this disclosure should not be perceived as limiting this invention. Various alternative embodiments and operational techniques will become clear to persons skilled in the art from this disclosure.

What is claimed is:

1. A method for manufacturing a film bulk acoustic resonator, comprising:
forming a closed room in a supporting substrate;
forming a bottom electrode above the closed room, the bottom electrode provided on a surface of the supporting substrate;
forming a piezoelectric film on a surface of the bottom electrode;
forming a top electrode facing the bottom electrode so as to sandwich the piezoelectric film between the top electrode and the bottom electrode;
forming an opening connected to the closed room from the surface of the supporting substrate; and
forming a cavity by removing a portion of the supporting substrate under the bottom electrode through the opening and the closed room.

2. The method of claim 1, wherein the cavity is formed so as to expose an under side of the bottom electrode.

3. The method of claim 1, wherein the supporting substrate is a silicon substrate having a {110} orientation.

4. The method of claim 1, wherein the supporting substrate is a silicon substrate having a {100} orientation.

5. The method of claim 1, wherein the supporting substrate is formed by bonding a first mother substrate and a second mother substrate with an adhesive layer so as to internally confine a trench formed at a surface of one of the first and second mother substrates, forming the closed room by the internally confined trench.

6. The method of claim 1, wherein the cavity is formed by anisotropic wet etching of the supporting substrate.

7. The method of claim 1, wherein the supporting substrate is a silicon on nothing substrate.

8. The method of claim 1, wherein the supporting substrate is formed by bonding a first mother substrate having a trench and a second mother substrate with an adhesive layer so as to internally confine the trench, forming the closed room by the internally confined trench.

9. The method of claim 5, wherein the adhesive layer is one of a silicon oxide film, a silicon nitride film, a spin on glass film, a spin on dielectric film, a polyimide film, a resist film, and a carbon film.

10. The method of claim 8, wherein the adhesive layer is a silicon oxide film formed on a surface of the first mother substrate.

11. The method of claim 8, wherein the adhesive layer is a silicon oxide film formed on a surface of the second mother substrate.

12. The method of claim 8, wherein the second mother substrate is a silicon substrate having a {110} orientation.

13. The method of claim 8, wherein the second mother substrate is a silicon substrate having a {100} orientation.

14. The method of claim 12, wherein the first mother substrate is a silicon substrate having one of a {110} orientation and a {100} orientation.

15. The method of claim 13, wherein the first mother substrate is a silicon substrate having one of a {110} orientation and a {100} orientation.
